(19) United States
(12) Patent Application Publication
(10) Pub. No.: US 2026/0250833 A1
(43) Pub. Date: Aug. 27, 2026

(54) SPUTTERING UNIT FOR PROCESSING SUBSTRATE IN VERTICAL POSITION

(71) Applicant: S.E.A Co., Ltd., Gyeongsangbuk-do (KR)

(72) Inventor: Jaeho Shin, Gumi-si (KR)

(21) Appl. No.: 19/234,669

(22) Filed: Jun. 11, 2025

(30) Foreign Application Priority Data
Feb. 27, 2025 (KR) 10-2025-0025682

(51) Int. Cl. C23C 14/34; C23C 14/02; C23C 14/50

(52) U.S. Cl. CPC C23C 14/34; C23C 14/02; C23C 14/505

(57) ABSTRACT

Disclosed is a sputtering unit having a structure including a rotating chamber that yaw-rotates a substrate in a vertical position to provide it to a sputtering chamber while handling the substrate in the vertical position, a substrate processing apparatus including the same, and an operating method thereof.

### CROSS-REFERENCE TO RELATED APPLICATION

This application claims the benefit of priority under 35 U.S.C. § 119 to Korean Patent Application No. 10-2025-0025682 filed on February 27, 2025, in the Korean Intellectual Property Office (KIPO), the entire contents of which are incorporated herein by reference.

### BACKGROUND

### TECHNICAL FIELD

The embodiments below are technologies related to a sputtering unit that processes a substrate in a vertical position.

### BACKGROUND OF THE INVENTION

A substrate processing apparatus is used to perform a surface processing step of sputtering such as circuit formation or plating on a product such as a substrate.

Such a substrate processing apparatus usually performs a transfer and sputtering process on a substrate in a horizontal position (a position in which a plane direction of the substrate is a vertical direction). Accordingly, an existing substrate processing apparatus has a disadvantage in that a large amount of space for equipment is required, and a substrate in a horizontal position is sputtered only on an upper surface of a flat surface, resulting in poor productivity. A technique for an existing substrate processing apparatus is disclosed in Korean Patent Application Publication No. 10-2005-0032251.

Accordingly, a technique for improving productivity and miniaturization of a substrate processing apparatus needs to be proposed.

### SUMMARY

### Problem to be Solved

In order to improve productivity and miniaturization of a substrate processing apparatus that performs a sputtering process, some embodiments propose a sputtering unit having a structure including a rotating chamber that yaw-rotates a substrate in a vertical position to provide it to a sputtering chamber while handling the substrate in the vertical position, a substrate processing apparatus including the same, and an operating method thereof.

However, the technical problems to be solved by the present invention are not limited to the above problems, and may be variously extended without departing from the technical spirit and scope of the present invention.

### Method for Solving Problem

According to an embodiment, a sputtering unit may include: a rotating chamber that yaw-rotates a substrate in a vertical position that is transferred and provide it to at least one sputtering chamber; and at least one sputtering chamber that performs sputtering on one surface of the substrate in the yaw-rotated vertical position while being connected to at least one side of the rotating chamber.

According to one aspect, the at least one sputtering chamber may be configured to sputter a target on one side in a horizontal direction.

According to another aspect, the rotating chamber may yaw-rotate the substrate in the vertical position so that one surface of the substrate in the vertical position faces one side of the horizontal direction that sputters the target in the at least one sputtering chamber.

According to another aspect, the rotating chamber may yaw-rotate the substrate in the vertical position so that the other surface opposite to the one surface of the substrate in the vertical position faces the one side in the horizontal direction of sputtering the target in the at least one sputtering chamber to provide it to the at least one sputtering chamber; and the at least one sputtering chamber may perform sputtering on the other surface of the substrate in the vertical position.

According to another aspect, the vertical position of the substrate may mean a position in which a plane direction of the substrate is a horizontal direction.

According to another aspect, the at least one sputtering chamber may be positioned opposite to the rotating chamber 121 and may be provided in two.

According to another aspect, the rotating chamber may yaw-rotate and provide the substrate in the vertical position with each of two sputtering chambers disposed opposite to the rotating chamber.

According to another aspect, the sputtering unit may further include: a pretreatment chamber that performs pretreatment on one surface of the substrate in the vertical position before performing the sputtering, while being connected to one side of the rotating chamber.

According to another aspect, the sputtering unit may further include: a heat treatment chamber that performs heat treatment on one surface of the substrate in the vertical position before performing the sputtering, while being connected to one side of the rotating chamber.

According to another aspect, the rotating chamber may yaw-rotate the substrate in the vertical position to provide the substrate in the vertical position to either the pretreatment chamber or the heat treatment chamber.

According to an embodiment, a sputtering method for a sputtering unit may include: a step of yaw-rotating, in a rotating chamber included in the sputtering unit, a substrate in a vertical position that is transferred to provide at least one sputtering chamber included in the sputtering unit; and a step of performing, in the at least one sputtering chamber connected to at least one side of the rotating chamber, sputtering on one surface of the substrate in the yaw-rotated vertical position.

### Effects of the Invention

Some embodiments propose a sputtering unit having a structure including a rotating chamber that yaw-rotates a substrate in a vertical position to provide it to a sputtering chamber while handling the substrate in the vertical position, a substrate processing apparatus including the same, and an operating method thereof, thereby making it possible to improve productivity and miniaturization of the substrate processing apparatus that performs a sputtering process.

However, the effects of the present invention are not limited to the above effects, and may be variously extended without departing from the technical spirit and scope of the present invention.

### BRIEF DESCRIPTION OF THE DRAWINGS

FIG. 1 is a plan view illustrating a substrate processing apparatus according to an embodiment.

FIGS. 2-4 are enlarged plan views illustrating a portion of a sputtering unit for describing a rotation function of a rotating chamber in a sputtering unit according to an embodiment.

FIG. 5 is a flow chart illustrating a sputtering method according to an embodiment.

### DETAILED DESCRIPTION

Hereinafter, embodiments of the present invention will be described in detail with reference to the accompanying drawings so that those skilled in the art may easily implement the embodiments. Since the description of the present invention is merely an example for structural or functional description, the scope of the present invention should not be construed as being limited by the example described in the text.

That is, it should be understood that the scope of the present invention includes equivalents that may realize the technical idea, because the present invention is not limited to the embodiments described herein because various changes are possible and various different forms can be implemented.

On the other hand, the meaning of the terms described in the present invention should be understood as follows.

The terms “first,” “second,” and the like are intended to distinguish one component from another, and the scope of rights should not be limited by these terms. For example, a first component may be termed a second component, and similarly a second component may also be termed a first component.

When a component is referred to as being “connected” to another component, it should be understood that it may be directly connected to that other component, but there may be another component in between. On the other hand, when it is stated that a component is “directly connected” to another component, it should be understood that there is no other component in the middle. On the other hand, other expressions describing the relationship between the components, i.e., “between” and “directly between” or “neighboring to” and “direct neighboring to”, etc., should be construed as well.

It is to be understood that the singular forms “a,” “an,” and “the” include plural referents unless the context clearly dictates otherwise, and that the terms “comprises” or “has” or the like are intended to designate the presence of an embodied feature, number, step, operation, component, part, or combination thereof, and do not preclude the possibility of the presence or addition of one or more other features, numbers, steps, operations, components, parts, or combinations thereof.

For each step, an identification code (e.g., a, b, c, etc.) is used for convenience of description, and the identification code does not describe the order of each of the steps, and each of the steps may occur differently from the specified order unless the context clearly describes a specific order. That is, each of the steps may occur in the same order as specified, may be performed substantially simultaneously, or may be performed in the opposite order.

Unless defined otherwise, all terms used herein have the same meaning as commonly understood by one of ordinary skill in the art to which this invention belongs. Terms defined in commonly used dictionaries should be interpreted as being consistent with their meaning in the context of the relevant art and may not be interpreted as having an ideal or overly formal meaning unless expressly defined herein.

It is noted that the figures are schematic and not drawn to scale. The relative dimensions and proportions of the portions in the figures are shown exaggerated or reduced in size for clarity and convenience in the figures and any dimensions are illustrative only and not limiting. And to the same structures, elements, or components shown in more than one figure, the same reference numerals are used to indicate similar features.

The embodiment according to the invention specifically represents an ideal embodiment of the invention. As a result, various modifications of the illustration are envisaged. The embodiments are thus not limited to the particular form of the region shown, but also include modifications of the form, for example by manufacture.

Hereinafter, with reference to the accompanying drawings, a process connection apparatus and an operating method thereof in a substrate processing process that automates integration of a vertical process which is the processing of substrates in carrier units in which substrates are placed in a vertical position and a horizontal process in which cleaning and drying are performed on a substrate-by-substrate basis for each of substrates in a horizontal position are described in order to improve productivity and quality stability in a chemical processing and a cleaning and drying process of a substrate.

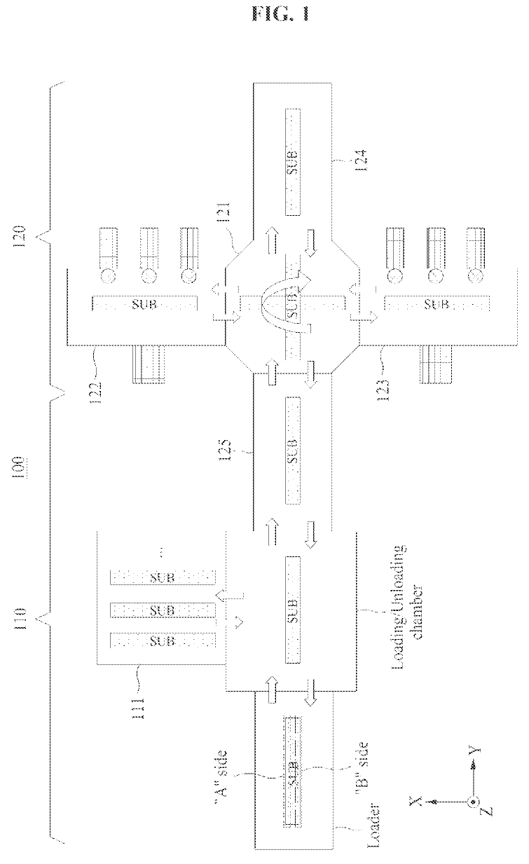

FIG. 1 is a plan view illustrating a substrate processing apparatus according to an embodiment.

Referring to FIG. 1, a substrate processing apparatus 100 according to an embodiment may include a substrate transferring unit 110 and a sputtering unit 120.

Hereinafter, the substrate (SUB) means not only a substrate based on a semiconductor material, but also a base layer composed of various materials to be sputtered.

In addition, a vertical position of the substrate (SUB) hereinafter means a position in which the plane direction of the substrate (SUB) is horizontal direction. That is, the “vertical position” means a position in which a flat large surface of the substrate (SUB) is included in a preset angle range with respect to an imaginary surface orthogonal to the ground. As an example, the “vertical position” may mean a position in which a flat wide surface of the substrate (SUB) is included within an angle range of 45 degrees to 135 degrees with respect to an imaginary surface orthogonal to the ground. The numerical values of the angular ranges are given by way of example only, and the numerical values of the angle ranges forming the condition of the “vertical position” may be set in various ways.

The substrate transferring unit 110 is a component configured to transfer the substrate (SUB) in the vertical position to be loaded to the sputtering unit 120, and a roller, a conveyor belt, and a magnetic levitation (maglev) may be used as a transfer method, but is not limited thereto.

A buffer 111 for temporarily storing the substrate (SUB) in the vertical position may be provided on one side of the substrate transferring unit 110. The buffer 111 may be omitted according to an implementation example, and the position may also be adaptively adjusted. In an example, the buffer 111 may be provided on one side of the sputtering unit 120, not on one side of a substrate transferring unit 110.

The sputtering unit 120 may include a rotating chamber 121 and at least one sputtering chamber 122, 123 as a component that performs sputtering on at least one surface A of the substrate (SUB) in the vertical position while being connected to one side of the substrate transferring unit 110.

The rotating chamber 121 may be configured to yaw-rotate the substrate (SUB) in the vertical position. In an example, the rotating chamber 121 may include rotating components for allowing the substrate (SUB) in the vertical position to yaw-rotate about a vertical axis.

The at least one sputtering chamber 122, 123 is positioned opposite to the rotating chamber 121 and may be provided in two. Accordingly, the rotating chamber 121 may provide the substrate (SUB) in the vertical position by yaw-rotating it to each of the two sputtering chambers 122 and 123 described However, the example of provision of at least one sputtering chamber 122, 123 is not limited or limited to that described.

In addition, the sputtering unit 120 may further include a pretreatment chamber 124 that performs pretreatment on the one surface A of the substrate (SUB) in the vertical position before performing sputtering while being connected to the one side of the rotating chamber 121, and/or a heat treatment chamber 125 that performs heat treatment on the one surface A of the substrate (SUB) in the vertical position before performing sputtering.

The sputtering unit 120 is characterized in that it performs sputtering on the one surface A of the substrate (SUB) in the vertical position in the at least one sputtering chamber 122, 123 by yaw-rotating a substrate in a vertical position (SUB) through the rotating chamber 121 to provide the substrate (SUB) in the vertical position to the at least one sputtering chamber 122, 123. A detailed description thereof will be described below.

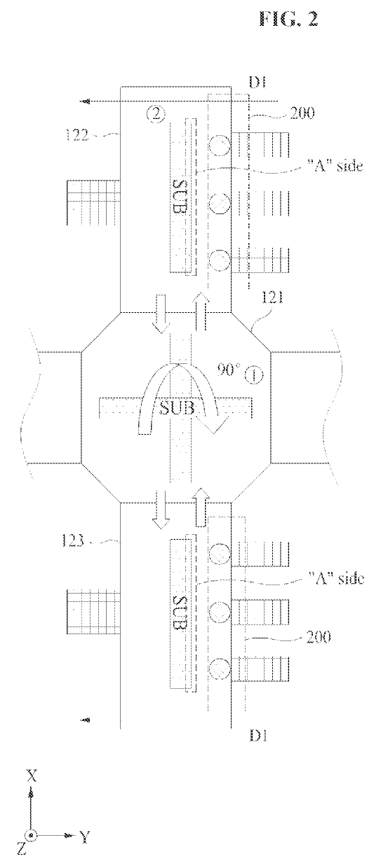

FIGS. 2 is an enlarged plan view illustrating a portion of a sputtering unit for describing a rotation function of a rotating chamber when performing sputtering on one surface of a substrate in a vertical position in the sputtering unit according to an embodiment.

Referring to FIG. 2, the sputtering unit 120 may include a rotating chamber 121 that yaw-rotates a substrate (SUB) in a vertical position to be transferred to provide the substrate (SUB) in the vertical position with at least one sputtering chamber 122, 123, and at least one sputtering chamber 122, 123 that is connected to at least one side of the rotating chamber 121 and performs sputtering on one surface A of the substrate (SUB) in the yaw-rotated vertical position.

The at least one sputtering chamber 122, 123 may be configured to sputter a target at one side 200 in the horizontal direction D1, as shown in the figure. Hereinafter, the fact that the at least one sputtering chamber 122, 123 is configured to sputter the target on one side 200 in the horizontal direction D1 means that the at least one sputtering chambers 122, 123 have a structure in which a sputtering target is provided on one side 200 which is a side wall of the at least one sputtering chamber 122, 123 so as to be able to sputter the target in the horizontal direction D1 as shown in the figure.

The rotating chamber 121 may yaw-rotate the substrate (SUB) in the vertical position such that one surface A of the substrate (SUB) in the vertical position faces one side 200 in the horizontal direction D1 of sputtering the target in the at least one sputtering chamber 122, 123.

For example, when the substrate (SUB) in the vertical position is transferred from the substrate transferring unit 110 as shown in FIG. 1, the rotating chamber 121 may yaw-rotate the substrate SUB of the vertical position by 90° along the clockwise direction such that one surface A of the substrate (SUB) in the vertical position faces one side 200 in the horizontal direction D1 of sputtering the target in the at least one sputtering chamber 122, 123 (①).

Accordingly, the at least one sputtering chamber 122, 123 may perform sputtering on the surface A of the substrate (SUB) in the vertical position (②).

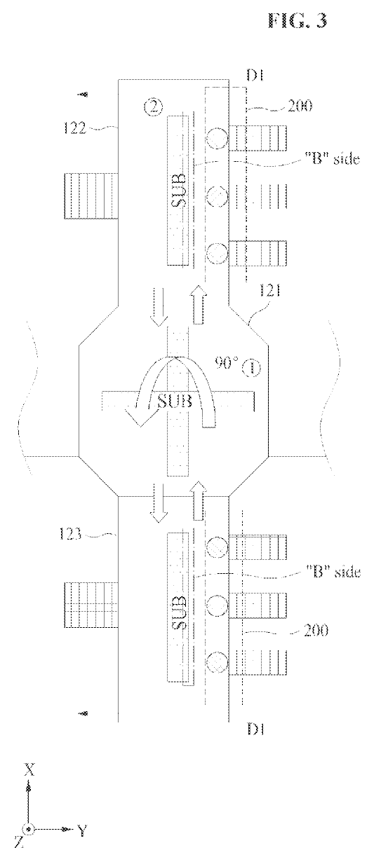

The rotating chamber 121 may vary the yaw-rotation of the substrate (SUB) in the vertical position, so that sputtering is performed on the other surface B opposite to the one surface A of the substrate (SUB) in the vertical position. A detailed description thereof will be described with reference to FIG. 3.

FIGS. 3 is an enlarged plan view illustrating a portion of a sputtering unit for describing a rotation function of a rotating chamber when performing sputtering on other side of a substrate in a vertical position in the sputtering unit according to an embodiment.

Referring to FIG. 3, the rotating chamber 121 may yaw-rotate the substrate (SUB) in the vertical position such that the other surface B of the substrate in the vertical positionSUB faces one side 200 in the horizontal direction D1 of sputtering the target in the at least one sputtering chamber 122, 123.

For example, when the substrate SUB in the vertical position is transferred from the substrate transferring unit 110 as shown in FIG. 1, the rotating chamber 121 may yaw-rotate the substrate (SUB) of the vertical position by 90° along the counterclockwise direction so that the other surface B of the substrate (SUB) faces one side 200 of the horizontal direction D1 of sputtering the target in the at least one sputtering chamber 122, 123 (①).

Accordingly, the at least one sputtering chamber 122, 123 may perform sputtering on the other surface B of the substrate (SUB) in the vertical position (②).

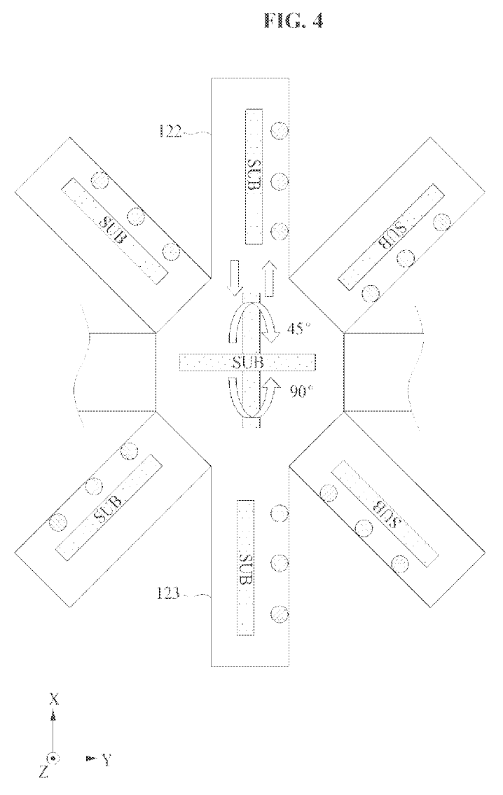

Although it has been described above that the at least one sputtering chamber 122, 123 is positioned opposite to the rotating chamber 121 and is provided in two, the rotating chamber 121 yaw-rotates and provides the substrate (SUB) in the vertical position to each of the described two sputtering chambers 122, 123, the present invention is not limited thereto, and the at least one sputtering chamber 122, 123 may be provided in three or more. A description thereof will be described with reference to FIG. 4.

FIGS. 4 is an enlarged plan view illustrating a portion of a sputtering unit for describing a rotation function of a rotating chamber when a plurality of sputtering chambers are included in the sputtering unit according to an embodiment.

Referring to FIG. 4, the at least one sputtering chamber 122, 123 may is positioned opposite to the rotating chamber 121 and is provided in six so as to be paired with each other. Accordingly, the rotating chamber 121 may selectively provide the substrate (SUB) in the vertical position to each of the six sputtering chambers 122, 123 by yaw-rotating the substrate SUB by 45° or 90° along the clockwise direction or the counterclockwise direction.

Although it has been described that the anomalous rotating chamber 121 yaw-rotates the substrate (SUB) in the vertical position to provide the substrate (SUB) in the vertical position to the at least one sputtering chamber 122, 123, the present disclosure is not limited thereto, and the rotating chamber 121 may yaw-rotate the substrate (SUB) in the vertical position to provide the substrate (SUB) in the vertical position to either the pretreatment chamber 124 or the heat treatment chamber 125.

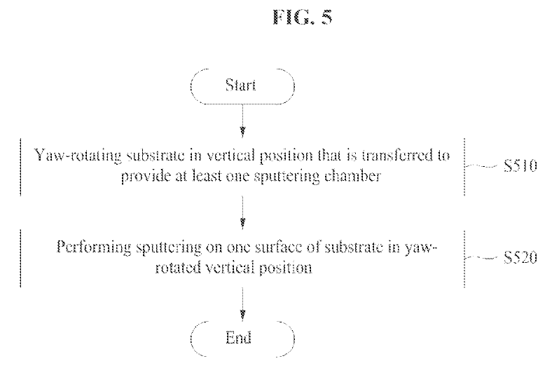

FIG. 5 is a flow chart illustrating a sputtering method according to an embodiment.

It is assumed that a sputtering method described below is performed by the sputtering unit 120 described above.

In step S510, the rotating chamber 121 included in the sputtering unit 120 may yaw-rotate the substrate (SUB) in the vertical position to be transferred and provide the substrate (SUB) to at least one sputtering chamber 122,123 included in the sputtering unit 120.

Accordingly, in step S520, the at least one sputtering chamber 122, 123 may perform sputtering on the one surface A of the substrate (SUB) in the yaw-rotated vertical position.

Although the above embodiments have been described by way of limited embodiments and drawings, various modifications and variations are possible from the above description to those skilled in the art. For example, suitable results may be achieved even if the described techniques are performed in a different order than the described method, and/or components of the described system, structure, apparatus, circuitry, etc. are combined or integrated in a different form than the described method or replaced or substituted by other components or equivalents.

Therefore, other implementations, other embodiments, and equivalents to the claims also fall within the scope of the following claims.

100 Substrate processing apparatus

110 Substrate transferring unit

111 Buffer

120 Sputtering unit

121 Rotating chamber

122, 123 At least one sputtering chamber

124 Pretreatment chamber

125 Heat treatment chamber

What is claimed is:

1. A sputtering unit, comprising:
a rotating chamber that yaw-rotates a substrate in a vertical position that is transferred and provide it to at least one sputtering chamber; and
at least one sputtering chamber that performs sputtering on one surface of the substrate in the yaw-rotated vertical position while being connected to at least one side of the rotating chamber.

2. The sputtering unit of claim 1,
wherein the at least one sputtering chamber is configured to sputter a target on one side in a horizontal direction.

3. The sputtering unit of claim 2,
wherein the rotating chamber yaw-rotates the substrate in the vertical position so that one surface of the substrate in the vertical position faces one side of the horizontal direction that sputters the target in the at least one sputtering chamber.

4. The sputtering unit of claim 3, wherein:
wherein the rotating chamber yaw-rotates the substrate in the vertical position so that the other surface opposite to the one surface of the substrate in the vertical position faces the one side in the horizontal direction of sputtering the target in the at least one sputtering chamber to provide it to the at least one sputtering chamber; and
the at least one sputtering chamber performs sputtering on the other surface of the substrate in the vertical position.

5. The sputtering unit of claim 1,
wherein the vertical position of the substrate means a position in which a plane direction of the substrate is a horizontal direction.

6. The sputtering unit of claim 1,
wherein the at least one sputtering chamber is positioned opposite to the rotating chamber 121 and is provided in two.

7. The sputtering unit of claim 6,
wherein the rotating chamber yaw-rotates and provides the substrate in the vertical position with each of two sputtering chambers disposed opposite to the rotating chamber.

8. The sputtering unit of claim 1,
wherein the sputtering unit further includes:
a pretreatment chamber that performs pretreatment on one surface of the substrate in the vertical position before performing the sputtering, while being connected to one side of the rotating chamber.

9. The sputtering unit of claim 1,
wherein the sputtering unit further includes:
a heat treatment chamber that performs heat treatment on one surface of the substrate in the vertical position before performing the sputtering, while being connected to one side of the rotating chamber.

10. The sputtering unit according to claim 8,
wherein the rotating chamber yaw-rotates the substrate in the vertical position to provide the substrate in the vertical position to either the pretreatment chamber or the heat treatment chamber.

11. A sputtering method for a sputtering unit, comprising:
a step of yaw-rotating, in a rotating chamber included in the sputtering unit, a substrate in a vertical position that is transferred to provide at least one sputtering chamber included in the sputtering unit; and
a step of performing, in the at least one sputtering chamber connected to at least one side of the rotating chamber, sputtering on one surface of the substrate in the yaw-rotated vertical position.
